(19) United States
(12) Patent Application Publication
(10) Pub. No.: US 2025/0293053 A1
(43) Pub. Date: Sep. 18, 2025

(54) SUBSTRATE PROCESSING APPARATUS AND METHOD OF REPLENISHING PROCESSING LIQUID

(71) Applicant: Tokyo Electron Limited, Tokyo (JP)

(72) Inventors: Hiroki SAKURAI, Koshi City (JP); Shogo MIZOTA, Koshi City (JP); Hiroshi KOMIYA, Koshi City (JP); Shinichi UMENO, Koshi City (JP); Shoki MIZUGUCHI, Koshi City (JP)

(21) Appl. No.: 19/074,646

(22) Filed: Mar. 10, 2025

(30) Foreign Application Priority Data
Mar. 12, 2024 (JP) 2024-038437

(51) Int. Cl. H01L 21/67

(52) U.S. Cl. CPC H01L 21/67017

(57) ABSTRACT

A substrate processing apparatus includes: a processing unit for performing liquid processing on a substrate using a processing liquid; a tank storing the processing liquid before being supplied to the processing unit; a replenishment line through which the processing liquid is supplied from a processing liquid source to the tank; an opening/closing valve for opening/closing the replenishment line; a first drain line branched at the replenishment line on an upstream side of the opening/closing valve; a first drainage opening/closing valve for opening/closing the first drain line; and a controller configured to control the opening/closing valve and the first drainage opening/closing valve to execute a preliminary drain operation in which the processing liquid flowing from the processing liquid source into the replenishment line is drained via the first drain line before a replenishment of the processing liquid from the processing liquid source into the tank via the replenishment line begins.

### CROSS-REFERENCE TO RELATED APPLICATION

This application is based upon and claims the benefit of priority from Japanese Patent Application No. 2024-038437, filed on Mar. 12, 2024, the entire contents of which are incorporated herein by reference.

### TECHNICAL FIELD

The present disclosure relates to a substrate processing apparatus and a method of replenishing a processing liquid.

### BACKGROUND

A semiconductor device manufacturing process includes a liquid processing process in which a chemical liquid (processing liquid) is supplied to a substrate to perform chemical cleaning or wet etching. In a substrate processing system that performs such a liquid processing process, a processing liquid supply system that supplies a processing liquid to a plurality of liquid processing units includes a tank that stores the processing liquid, and a circulation line which is connected to the tank at its both ends and through which the processing liquid circulates. The processing liquid is supplied to the plurality of liquid processing units via a plurality of branch lines connected to the circulation line. As substrate processing is repeated, the processing liquid in the tank decreases and the tank is replenished with a new processing liquid.

### PRIOR ART DOCUMENT

### Patent Document

Patent Document 1: Japanese Laid-Open Patent Publication No. 2013-175552

### SUMMARY

According to one embodiment of the present disclosure, a substrate processing apparatus includes: a processing unit configured to perform liquid processing on a substrate using a processing liquid; a tank storing the processing liquid before being supplied to the processing unit; a replenishment line through which the processing liquid is supplied from a processing liquid source to the tank; a replenishment opening/closing valve configured to open/close the replenishment line; a first drain line branched at the replenishment line on an upstream side of the replenishment opening/closing valve; a first drainage opening/closing valve configured to open/close the first drain line; and a controller configured to control the replenishment opening/closing valve and the first drainage opening/closing valve to execute a preliminary drain operation in which the processing liquid flowing from the processing liquid source into the replenishment line is drained via the first drain line before a replenishment of the processing liquid from the processing liquid source into the tank via the replenishment line begins.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view of a substrate processing system according to one embodiment of a substrate processing apparatus.

FIG. 2 is a piping system diagram showing an example of a configuration of a sulfuric acid supply mechanism of a processing liquid supply mechanism included in a substrate processing system, which shows a first embodiment of a sulfuric-acid replenishment mechanism included in the sulfuric acid supply mechanism.

FIG. 3 is a flowchart showing an example of a flow relating to a preliminary drain operation.

FIG. 4 is a flowchart showing another example of the flow relating to the preliminary drain operation.

FIG. 5 is a piping system diagram showing a second embodiment of the sulfuric-acid replenishment mechanism.

FIG. 6 is a piping system diagram showing a third embodiment of the sulfuric-acid replenishment mechanism.

FIG. 7 is a flowchart showing yet another example of the flow relating to the preliminary drain operation.

FIG. 8 is a piping system diagram showing a fourth embodiment of the sulfuric-acid replenishment mechanism.

FIG. 9 is a piping system diagram showing a fifth embodiment of the sulfuric-acid replenishment mechanism.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

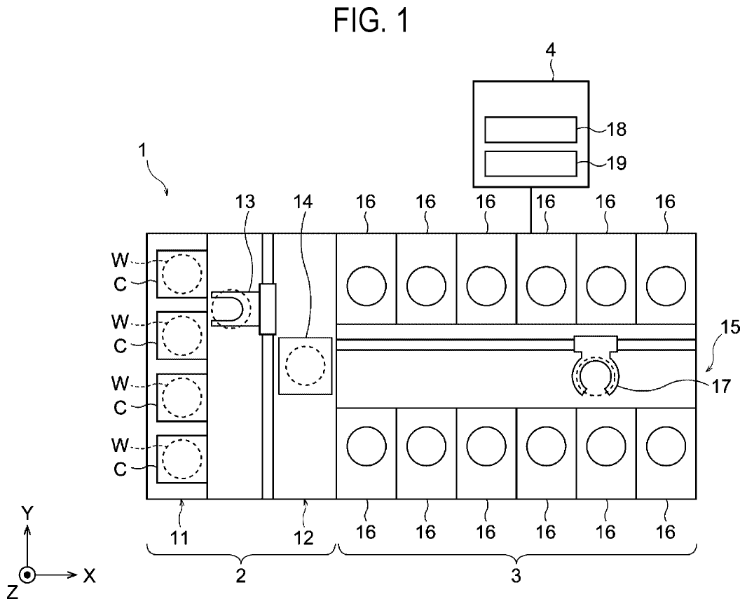

A schematic configuration of a substrate processing system 1 (an example of a liquid processing apparatus) according to an embodiment will be described with reference to FIG. 1. FIG. 1 is a view showing the schematic configuration of the substrate processing system 1 according to the embodiment. For the clarification of a positional relationship, an X-axis direction, a Y-axis direction and a Z-axis direction, which are orthogonal to one another, are defined in the following description and a positive Z-axis direction is defined as a vertical upward direction.

As shown in FIG. 1, the substrate processing system 1 includes a loading/unloading station 2 and a processing station 3.

The loading/unloading station 2 includes a carrier stage 11 and a transferrer 12. A plurality of carriers C that accommodate a plurality of substrates W (semiconductor wafers in this embodiment) to be processed in a horizontal position are placed on the carrier stage 11.

The transferrer 12 is provided with a substrate transfer device 13 and a deliverer 14. The substrate transfer device 13 may transfer the substrates W between the carrier C and the deliverer 14.

The processing station 3 includes a transferrer 15 and a plurality of processing units 16 arranged side by side on both sides of the transferrer 15.

The transferrer 15 is provided with a substrate transfer device 17. The substrate transfer device 17 may transfer the substrate W between the deliverer 14 and any of the processing units 16.

Each processing unit 16 performs liquid processing on the substrate W by supplying a processing fluid (processing liquid) to the substrate W.

The processing liquid may be any processing liquid used in the technical field of the semiconductor device manufacturing. Specifically, examples of the processing liquid may include chemical liquids such as DHF, SC1, and SC2, rinse liquids such as DIW (pure water), and organic substitution liquids with low surface tension such as IPA (isopropyl alcohol). In an exemplary embodiment to be described later, SPM (sulfuric acid/hydrogen peroxide mixture), SC1, binary fluid (DIW spray), and IPA are sequentially supplied to the substrate W in the processing unit 16.

The substrate processing system 1 includes a control device 4. The control device 4 is, for example, a computer, and includes a control operator 18 and a storage 19. The storage 19 stores programs for controlling various processes executed in the substrate processing system 1. The control operator 18 controls an operation of the substrate processing system 1 by reading and executing process recipes and control programs stored in the storage 19.

The process recipes and control programs may be recorded on a non-transitory computer-readable storage medium and installed from the storage medium in the storage 19 of the control device 4. Examples of the computer-readable storage medium may include a hard disk (HD), a flexible disk (FD), a compact disc (CD), a magnetic-optical disc (MO), a memory card and the like.

In the above-described substrate processing system 1, first, the substrate transfer device 13 of the loading/unloading station 2 takes out the substrate W from the carrier C placed on the carrier stage 11 and places the same on the deliverer 14. The substrate W placed on the deliverer 14 is taken out from the deliverer 14 by the substrate transfer device 17 of the processing station 3 and is loaded into the processing unit 16.

The substrate W loaded into the processing unit 16 is processed by the processing unit 16, and subsequently, is unloaded from the processing unit 16 by the substrate transfer device 17 and is placed on the deliverer 14. Then, the processed wafer W placed on the deliverer 14 is returned to the original carrier C on the carrier stage 11 by the substrate transfer device 13.

### Configuration of Processing Liquid Supply Mechanism

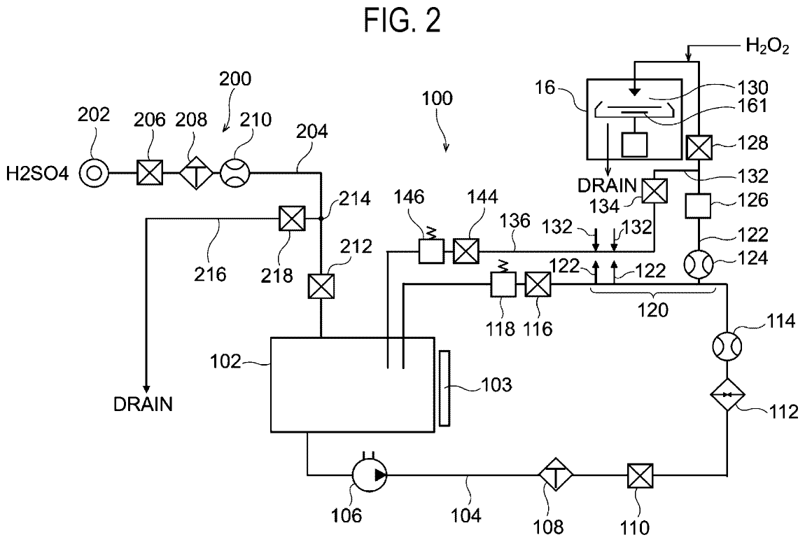

Next, a processing liquid supply mechanism that supplies the processing liquid to each processing unit 16 will be described with reference to FIG. 2. The processing liquid includes various liquids such as chemical liquids, rinse liquids such as DIW (pure water), and organic solvents such as IPA (isopropyl alcohol). Here, only a chemical liquid supply mechanism of the processing liquid supply mechanism, particularly a sulfuric acid supply mechanism 100 of a SPM supply mechanism that supplies SPM (the mixture of sulfuric acid and hydrogen peroxide) as a chemical liquid, will be described. As other processing liquid supply mechanisms, ones known in the technical field of the semiconductor manufacturing apparatus may be appropriately selected and used, and illustration and description thereof will be omitted.

The sulfuric acid supply mechanism 100 includes a tank 102 (storage tank) that stores the sulfuric acid, and a circulation line 104.

The circulation line 104 includes a pump 106, a filter 108, an opening/closing valve 110, a heater (in-line heater) 112, a flowmeter 114, an opening/closing valve 116, and a backing pressure valve 118, which are arranged sequentially from a side closer to the tank 102 (upstream side).

The circulation line 104 has a branch supply line connection area 120. In the branch supply line connection area 120, a plurality of branch supply lines 122 is branched at the circulation line 104. In FIG. 2, only one of the plurality of branch supply lines 122 is shown as a whole, and only upstream ends of other two branch supply lines 122 are indicated by arrows.

The branch supply line 122 includes a flowmeter 124, a flow control valve 126, and an opening/closing valve 128, which are arranged sequentially from the upstream side. A nozzle 130 in the processing unit 16 is provided in a downstream end of the branch supply line 122. The processing unit 16 includes a spin chuck 161 (substrate holder/rotator) that rotates the substrate W around a vertical axis while holding the substrate W in a horizontal posture. The nozzle 130 is supported by a nozzle arm (not shown) and may discharge the chemical liquid (in this embodiment, SPM which is the mixture of sulfuric acid and hydrogen peroxide) to any radial position of the substrate W held and rotated by the spin chuck 161. The processing unit 16 includes one or more nozzles for discharging other processing liquids (such as the above-mentioned SC1, IPA, and DIW), but they are not shown herein. A configuration of the processing unit 16 is well known in the technical field of the semiconductor manufacturing apparatus, and therefore, detailed description thereof will be omitted.

Between the flow control valve 126 and the opening/closing valve 128, a branch return line 132 is provided to be branched at the branch supply line 122. The number of branch return lines 132 is the same as that of the branch supply lines 122 (i.e., the same number as the processing units 16). Each branch return line 132 includes an opening/closing valve 134. The plurality of branch return lines 132 are joined in a main return line 136 at a branch return line join area 138 defined in the main return line 136. The main return line 136 is connected to the tank 102. In FIG. 2, only one of the plurality of branch return lines 132 is shown as a whole, and only downstream ends of other two branch return lines 132 are indicated by arrows.

The circulation line 104 is provided with the opening/closing valve 116 and the constant-pressure valve 118 on a downstream side of the branch supply line connection area 120. The constant-pressure valve 118 maintains a pressure of the sulfuric acid in the branch supply line connection area 120 at a substantially constant level, thereby easily controlling a flow rate of the sulfuric acid flowing through each branch supply line 122.

The main return line 136 is provided with an opening/closing valve 144 and a constant pressure valve 146 on a downstream side of the branch return line join area 138.

When SPM is not being supplied from the nozzle 130 to the substrate W, the opening/closing valve 128 remains closed and the opening/closing valve 134 remains opened, so that high-temperature sulfuric acid always flows through a portion of the branch supply line 122 and the branch return line 132. This prevents the sulfuric acid from cooling in the branch supply line 122, thereby reducing an amount of liquid required for a temperature-return dummy dispense.

During a normal operation of the substrate processing system, the sulfuric acid in the tank 102 circulates through the circulation line 104 and is heated by the heater 112 during the circulation. The sulfuric acid is supplied to each processing unit 16 via the branch supply line 122 according to a processing schedule of the substrate processing system. As shown diagrammatically in FIG. 2 by an arrow labeled H₂O₂, hydrogen peroxide is supplied to the branch supply line 122 from a supply line of the hydrogen peroxide supply mechanism at a position in front of the nozzle 130. This hydrogen peroxide is mixed with the sulfuric acid flowing through the branch supply line 122, thereby generating SPM, which is the mixture of sulfuric acid and hydrogen peroxide. The SPM is supplied from the nozzle 130 to the substrate W which is being rotated. Thus, the substrate W is subjected to SPM processing (chemical liquid processing).

During the normal operation of the substrate processing system, as the substrates W are sequentially processed in each processing unit 16, the sulfuric acid in the tank 102 decreases. When a liquid level sensor 103 detects that a liquid level of the sulfuric acid in the tank 102 has dropped to a predetermined lower-limit liquid level, the tank 102 is replenished with the sulfuric acid. Next, a configuration (a sulfuric-acid replenishment mechanism 200) in which the sulfuric acid is replenishing will be described. Of course, the sulfuric-acid replenishment mechanism (processing liquid replenishment mechanism) 200 is also used when supplying a new sulfuric acid to an empty tank.

The sulfuric-acid replenishment mechanism 200 includes a sulfuric-acid replenishment line 204 that connects a sulfuric acid source 202 and the tank 102. As an example, the sulfuric acid source 202 is provided as a factory power of a semiconductor device manufacturing factory in which the substrate processing system 1 is installed. In this case, the sulfuric acid source 202 is an auxiliary facility of the semiconductor device manufacturing factory and is not a part of the substrate processing system 1. The sulfuric acid source 202 may be constituted with a tank storing a processing liquid provided by a chemical liquid manufacturer, and a forcibly-feeding mechanism that supplies a pressurized inert gas to the tank and sends out the sulfuric acid from the tank.

The sulfuric-acid replenishment line 204 includes an opening/closing valve 206, a filter 208, a flowmeter 210, and an opening/closing valve 212, which are arranged sequentially from the upstream side. At a branch point 214 on a secondary side of the filter 208, that is, on a downstream side of the filter 208, a drain line 216 is branched at the sulfuric-acid replenishment line 204. An opening/closing valve 218 is provided in the drain line 216. A downstream end of the drain line 216 is connected to, for example, a factory waste liquid path.

An operation of the sulfuric-acid replenishment mechanism 200 will be described below. During the normal operation of the substrate processing system, when the liquid level sensor 103 detects that the liquid level of sulfuric acid in the tank 102 has dropped to the predetermined lower-limit liquid level, the opening/closing valves 206 and 212 of the sulfuric-acid replenishment line 204 are opened with the opening/closing valve 218 of the drain line 216 closed. As a result, the sulfuric acid is supplied to (replenished into) the tank 102 from the sulfuric acid source 202 via the sulfuric-acid replenishment line 204. When the liquid level sensor 103 detects that the liquid level of the sulfuric acid in the tank 102 has reached the predetermined upper-limit liquid level, the opening/closing valves 206 and 212 are closed to stop the replenishment of the sulfuric acid into the tank 102.

When the operation of the substrate processing system is resumed after the operation of the substrate processing system has been stopped for a relatively long period of time, the sulfuric acid, which has stayed in the sulfuric-acid replenishment line 204 during the stop of the operation, is first discarded via the drain line 216, and then the tank 102 is replenished with the sulfuric acid in response to a sulfuric-acid replenishment request. In other words, the sulfuric acid, which has stayed in the sulfuric-acid replenishment line 204 for a long period of time, is discarded without being supplied to the tank 102. This operation is referred to as a “preliminary drain operation.”

When the sulfuric acid stays in the sulfuric-acid replenishment line 204 for a long period of time, contaminants such as particles trapped in the filter 208 (particularly particles smaller than fine pores adhering to a filter element surface by a non-sieving mechanism) may be released from the filter 208. In addition, contaminants adhering to the opening/closing valve 206 and the sulfuric-acid replenishment line (pipe) 204 may be released or dissolved into the sulfuric acid. When the sulfuric acid containing such contaminants is supplied to the tank 102, an amount of contaminants contained in the sulfuric acid flowing through the circulation line 104 increases. Although the filter 108 provided in the circulation line 104 may remove the contaminants such as particles, it is difficult to remove all of them. Therefore, the amount of particles adhering to the substrate W processed in the processing unit 16 may increase. For this reason, it is desirable to maintain a high degree of cleanliness of the sulfuric acid supplied to the tank 102 via the sulfuric-acid replenishment line 204. To do this, the preliminary drain operation is executed.

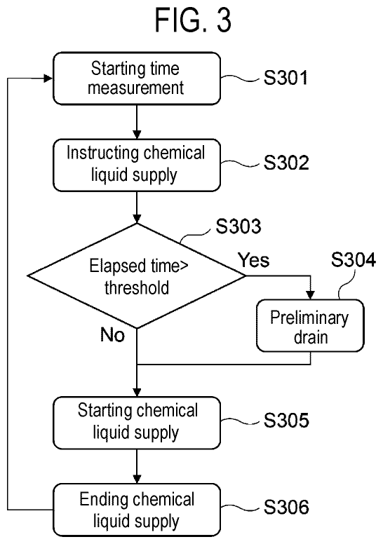

An example of a specific flow relating to the preliminary drain operation is shown in FIG. 3.

The control device 4 uses its timer function to measure a time period elapsed from when the replenishment of the tank 102 with a time point when the sulfuric acid is lastly performed as a starting point (Step S301 in FIG. 3). When the liquid level in the tank 102 is detected to have dropped to the lower-limit liquid level, the control device 4 determines that the replenishment (supply) of the tank 102 with the sulfuric acid is required (Step S302). Thereafter, the control device 4 determines whether or not the elapsed time period exceeds a predetermined threshold (Step S303).

When the elapsed time period is determined to exceed the threshold (“Yes” in Step S303), the preliminary drain operation is executed (Step S304). In the preliminary drain operation, the opening/closing valve 206 of the sulfuric-acid replenishment line 204 and the opening/closing valve 218 of the drain line 216 are opened with the opening/closing valve 212 of the sulfuric-acid replenishment line 204 closed. As a result, new sulfuric acid flows from the sulfuric acid source 202 into the sulfuric-acid replenishment line 204, and the sulfuric acid thus flown is discharged from the drain line 216. Thus, the sulfuric acid containing contaminants such as particles, which have stayed on the upstream side of the branch point 214 of the sulfuric-acid replenishment line 204, is discharged via the drain line 216.

The preliminary drain operation is executed for a predetermined period of time using the above-mentioned timer function. Alternatively, the preliminary drain operation may be performed until an integrated flow rate of the sulfuric acid during the preliminary drain operation reaches a predetermined value. The integrated flow rate of the sulfuric acid may be determined by, for example, a time integration of detection values of the flowmeter 210 provided in the sulfuric-acid replenishment line 204.

The above-mentioned predetermined period of time or the above-mentioned predetermined value of the integrated flow rate may be determined based on an amount of residual sulfuric acid (which substantially corresponds to, for example, an inner capacity of the sulfuric-acid replenishment line 204 on the upstream side of the branch point 214) and a discharge flow rate of the sulfuric acid during the preliminary drain operation. For example, a condition of the preliminary drain operation may be determined so that an amount of the sulfuric acid, for example, five times the amount of residual sulfuric acid (this amount is determined based on a preliminary experiment in consideration of a safety margin), is discarded via the drain line 216.

After the preliminary drain operation is completed, the opening/closing valve 218 of the drain line 216 is closed and the opening/closing valve 212 of the sulfuric-acid replenishment line 204 is opened, so that the tank 102 is replenished with the sulfuric acid (Step S305). When the replenishment of a required amount of the sulfuric acid is completed, the opening/closing valves 206 and 212 of the sulfuric-acid replenishment line 204 are closed (Step S306), the timer is reset, and a time period elapsed from when the timer is reset is measured again (Step S301).

When it is determined in Step S303 that the elapsed time period does not exceed the threshold (“No” in Step S303), the opening/closing valves 206 and 212 of the sulfuric-acid replenishment line 204 are opened with the opening/closing valve 218 of the drain line 216 closed, and the tank 102 is replenished with the sulfuric acid without performing the above-described preliminary drain operation. Even in this case, when the replenishment of the sulfuric acid is completed, the opening/closing valves 206 and 212 of the sulfuric-acid replenishment line 204 are closed, the timer is reset, and the time period elapsed from when the timer is reset is measured again.

When the preliminary drain operation is being performed, the flow rate of the sulfuric acid flowing through the sulfuric-acid replenishment line 204 may be changed. This may enhance effectiveness of the preliminary drain operation in discharging contaminants such as particles. Such a change in flow rate may be achieved by providing a flow control valve on the upstream side of the branch point 214 of the sulfuric-acid replenishment line 204.

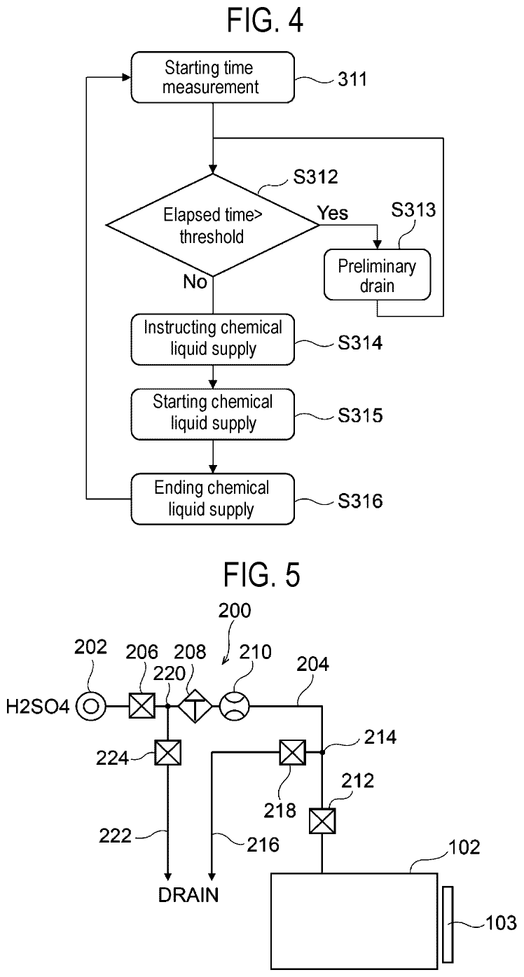

Another example of the specific flow is shown in FIG. 4. Unlike the flow of FIG. 3 in which whether or not the preliminary drain operation is required is determined with a timing when the supply of the chemical liquid is required as a trigger, the flow in this example periodically executes the preliminary drain operation.

The control device 4 uses the timer function to measure a time period elapsed from when the replenishment of the tank 102 with the sulfuric acid is lastly performed, or a time period elapsed from when the preliminary drain operation is lastly executed (Step S311 in FIG. 4). When the elapsed time period exceeds a predetermined threshold (“Yes” in Step S312), the opening/closing valve 212 of the sulfuric-acid replenishment line 204 is closed, and the opening/closing valve 206 of the sulfuric-acid replenishment line 204 and the opening/closing valve 218 of the drain line 216 are opened, and the preliminary drain operation is executed (Step S313). When the preliminary drain operation ends, the timer is reset. The elapsed time is measured again with a time when the timer is reset as a starting time. Each time the elapsed time period reaches the predetermined threshold, the preliminary drain operation is executed (in a loop composed of Steps S312 and S313).

When the liquid level sensor 103 detects that the liquid level in the tank 102 has dropped to the lower-limit liquid level at a time point when the elapsed time period does not reach the predetermined threshold (“No” in Step S312), the control device 4 determines that the tank 102 needs to be replenished with the sulfuric acid (Step S314). Then, the control device 4 opens the opening/closing valves 206 and 212 of the sulfuric-acid replenishment line 204 with the opening/closing valve 218 of the drain line 216 closed, thereby replenishing the tank 102 with the sulfuric acid (Step S315). When the replenishment of a required amount of the sulfuric acid is completed, the opening/closing valves 206 and 212 of the sulfuric-acid replenishment line 204 are closed (Step S316), the timer is reset, and the elapsed time period is measured again with a time when the timer is reset as a starting point (Step S311).

Next, another embodiment (hereinafter also referred to as a second embodiment) of the sulfuric-acid replenishment mechanism will be described with reference to FIG. 5. The second embodiment is different from the embodiment shown in FIG. 2 (hereinafter also referred to as a first embodiment) in that an additional drain line 222 is further provided, and other features in the second embodiment are the same as those in the first embodiment. The same members as those in the first embodiment will be denoted by the same reference numerals, and descriptions thereof will be omitted. Even when the sulfuric-acid replenishment mechanism according to the second embodiment is used, a configuration of the sulfuric acid supply mechanism (not shown) other than the sulfuric-acid replenishment mechanism is the same as that shown in FIG. 2.

As shown in FIG. 5, the additional drain line 222 is branched at the sulfuric-acid replenishment line 204 at a branch point 220 set on the primary side (upstream side) of the filter 208, specifically between the opening/closing valve 206 and the filter 208. The additional drain line 222 includes an opening/closing valve 224. In the following description, the drain line 216 may be referred to as a first drain line 216, and the additional drain line 222 may be referred to as a second drain line 222.

An operation of the sulfuric-acid replenishment mechanism 200 of the second embodiment will be described below. During the normal operation of the substrate processing system, when the liquid level sensor 103 detects that the liquid level of the sulfuric acid in the tank 102 has dropped to the predetermined lower-limit liquid level, the opening/closing valves 206 and 212 of the sulfuric-acid replenishment line 204 are opened with the opening/closing valve (first drainage opening/closing valve) 218 of the first drain line 216 and the opening/closing valve (second drainage opening/closing valve) 222 of the second drain line 222 closed. As a result, the sulfuric acid is supplied (replenished) to the tank 102 from the sulfuric acid source 202 via the sulfuric-acid replenishment line 204. When the liquid level sensor 103 detects that the liquid level of the sulfuric acid in the tank 102 has reached the predetermined upper-limit liquid level, the opening/closing valves 206 and 212 of the sulfuric-acid replenishment line 204 are closed to stop the replenishment of the tank 102 with the sulfuric acid.

When the sulfuric acid stays in the sulfuric-acid replenishment line 204 for a long period of time, the preliminary drain operation is executed as in the first embodiment. The preliminary drain operation in the second embodiment includes a first preliminary drain operation which is initially executed, and a second preliminary drain operation which is executed after the first preliminary drain operation.

When executing the first preliminary drain operation, the opening/closing valve 224 of the second drain line 222 is opened with the opening/closing valve 218 of the first drain line 216 and the opening/closing valve 212 of the sulfuric-acid replenishment line 204 closed. Then, new sulfuric acid flows from the sulfuric acid source 202 into the sulfuric-acid replenishment line 204, and the sulfuric acid thus flown is discharged from the second drain line 222. As a result, the sulfuric acid containing contaminants such as particles, which stay on the upstream side (the primary side of the filter 208) of the branch point 220 of the sulfuric-acid replenishment line 204, is discharged.

For example, when the sulfuric acid source 202 is used for a factory power, even if the sulfuric acid stays in a sulfuric acid flow path at a connection portion with the sulfuric-acid replenishment line 204 of the factory power and on an upstream side of the connection portion, contaminants such as particles may be released or dissolved into the sulfuric acid. In addition, contaminants such as particles may be released or dissolved into the sulfuric acid in an upstream portion of the filter 208 of the sulfuric-acid replenishment line 204. By executing the first preliminary drain operation, it is possible to discharge the sulfuric acid containing such contaminants.

The first preliminary drain operation is executed for a predetermined period of time using the above-mentioned timer function. The first preliminary drain operation may be executed until the integrated flow rate of the sulfuric acid during the preliminary drain operation reaches a predetermined value. In the configuration of FIG. 5, the integrated flow rate during the first preliminary drain operation may not be measured using the flowmeter 210. Thus, in order to measure the integrated flow rate, the position of the flowmeter 210 may be changed to a position where the flow rate of the sulfuric acid discharged via the second drain line 222 may be measured (for example, a position on the upstream side of the branch point 220 of the sulfuric-acid replenishment line 204), or another flowmeter may be provided in the second drain line 222.

After the first preliminary drain operation is completed, the second preliminary drain operation begins. When executing the second preliminary drain operation, in the state in which the opening/closing valve 212 of the sulfuric-acid replenishment line 204 remains closed, the opening/closing valve 224 of the second drain line 222 is closed, and the opening/closing valve 218 of the first drain line 216 is opened. Then, new sulfuric acid flows from the sulfuric acid source 202 into the sulfuric-acid replenishment line 204. The sulfuric acid thus flown is discharged from the first drain line 216. As a result, the sulfuric acid containing contaminants such as particles, which stay in the filter 208 of the sulfuric-acid replenishment line 204 and on the downstream side of the filter 208, is discharged.

The second preliminary drain operation is executed for a predetermined period of time using the above-mentioned timer function. The second preliminary drain operation may be executed until the integrated flow rate of the sulfuric acid during the preliminary drain operation reaches a predetermined value.

Even in the case of executing the above-described first preliminary drain operation and second preliminary drain operation, the operations according to the flows of FIGS. 3 and 4 may be performed. In this case, the “preliminary drain operation” in the flowchart may be read as “the first preliminary drain operation” and “the second preliminary drain operation.”

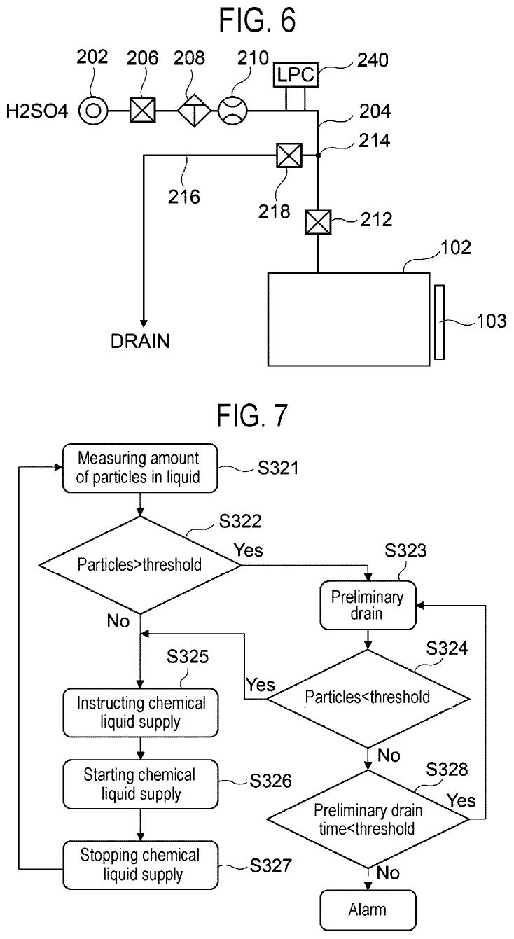

Next, still another embodiment (hereinafter also referred to as a third embodiment) of the sulfuric-acid replenishment mechanism will be described with reference to FIG. 6. The second embodiment is different from the first embodiment shown in FIG. 2 in that a liquid particle counter (particle detector) 240 (hereinafter referred to as “LPC”) is provided in the sulfuric-acid replenishment line 204, and other features are the same as those of the first embodiment. The same members as those in the first embodiment will be denoted by the same reference numerals, and descriptions thereof will be omitted. Even when the sulfuric-acid replenishment mechanism according to the third embodiment is used, a configuration of the sulfuric acid supply mechanism (not shown) other than the sulfuric-acid replenishment mechanism is the same as that shown in FIG. 2.

As shown in FIG. 6, the LPC 240 is provided on the secondary side (downstream side) of the filter 208 of the sulfuric-acid replenishment line 204 and on the upstream side of the branch point 214 of the drain line 216.

A specific operation example relating to the preliminary drain operation in the third embodiment will be describe below.

### Operation Example 1

When the liquid level sensor 103 detects that the liquid level of the sulfuric acid in the tank 102 has dropped to the lower-limit liquid level, the control device 4 determines that it is necessary to supply the chemical liquid. Then, the control device 4 executes the preliminary drain operation to discharge the sulfuric acid which stays in the sulfuric-acid replenishment line 204 by opening the opening/closing valve 206 of the sulfuric-acid replenishment line 204 and the opening/closing valve 218 of the drain line 216 with the opening/closing valve 212 of the sulfuric-acid replenishment line 204 closed. During such a discharge operation, the LPC 240 detects an amount of particles contained in the sulfuric acid passing through the LPC 240.

The LPC 240 may detect the amount of particles in real time. The control device 4 may determine in real time whether or not the amount of particles exceeds a predetermined threshold. The LPC 240 may sample data at a predetermined time interval. The control device 4 may determine whether or not the amount of particles exceeds the predetermined threshold based on an average value of pieces of sampling data obtained in a plurality of samplings. The LPC 240 may sample data at a predetermined time interval, and the control device 4 may determine whether or not the amount of particles exceeds the predetermined threshold based on a moving average of pieces of sampling data obtained in a plurality of samplings. Hereinafter, in this specification, the amount of particles compared with the threshold may be any of the above-described real-time measurement value, average value, and moving average.

When the amount of particles is determined to be lower than the predetermined threshold, the control device 4 stops the preliminary drain operation and begins the replenishment of the tank 102 with the sulfuric acid. That is, the control device 4 closes the opening/closing valve 218 of the drain line 216 and opens the opening/closing valve 212 of the sulfuric-acid replenishment line 204 with the opening/closing valve 206 of the sulfuric-acid replenishment line 204 opened. When the liquid level sensor 103 detects that the liquid level of the sulfuric acid in the tank 102 has reached the predetermined upper-limit liquid level, the opening/closing valves 206 and 212 of the sulfuric-acid replenishment line 204 are closed to stop the replenishment of the tank 102 with the sulfuric acid.

When the amount of particles detected by the LPC 240 exceeds the predetermined threshold (due to some abnormality) while the tank 102 is being replenished with the sulfuric acid, the control device 4 closes the opening/closing valve 212 of the sulfuric-acid replenishment line 204 and opens the opening/closing valve 218 of the drain line 216. As a result, the replenishment of the tank 102 with the sulfuric acid is stopped, and the preliminary drain operation is executed again.

### Operation Example 2

Operation Example 2 relating to the preliminary drain operation in the third embodiment will be described with reference to a flowchart in FIG. 7.

When a next replenishment time approaches after the previous replenishment of the tank 102 with the sulfuric acid, the LPC 240 measures an amount of particles in the sulfuric acid which stays in the sulfuric-acid replenishment line 204. During the normal operation of the substrate processing system, the liquid in the tank 102 decreases at a substantially steady pace. Therefore, the approach of the next replenishment time may be detected by the above-mentioned timer based on a time period elapsed from when the replenishment of the sulfuric acid is completed. In a case in which the liquid level detector provided in the tank 102 is configured to detect that the liquid level in the tank 102 is slightly higher than the lower-limit liquid level, the liquid level detector may detect that the next replenishment time is approaching.

When the sulfuric acid is in a stationary state in the sulfuric-acid replenishment line 204, the LPC 240 may not validly measure the amount of particles. This is because problematic particles are dispersed in the sulfuric acid when the sulfuric acid starts to move. For this reason, the measurement of the amount of particles in the sulfuric acid (Step S321 in FIG. 7) is performed while the sulfuric acid is moving, in this case, while executing the preliminary drain operation. The preliminary drain operation is executed by opening the opening/closing valve 206 and the opening/closing valve 218 with the opening/closing valve 212 closed, as in the first embodiment.

The amount of particles measured by the LPC 240 is compared with a predetermined threshold (Step S322).

When the amount of particles is greater than the predetermined threshold (“Yes” in Step S322), the preliminary drain operation is executed (Step S323). In the case in which the moving average is measured as described above, the preliminary drain operation is continued in-situ. After the timer detects that the preliminary drain operation has been executed for the predetermined period of time (or after it is confirmed that a predetermined amount of the sulfuric acid has been discarded from the drain line 216 based on a detection value obtained by the flowmeter 210), the amount of particles measured by the LPC 240 is compared with the predetermined threshold (Step S324).

When the amount of particles becomes smaller than the predetermined threshold (“Yes” in Step S324), the control device 4 recognizes that there is no problem in replenishing the tank 102 with the sulfuric acid. Even when the determination result in Step S322 is “No,” the control device 4 recognizes that there is no problem in replenishing the tank 102 with the sulfuric acid, and the flow proceeds to Step S325.

In this state, when the liquid level sensor 103 detects that the liquid level of the sulfuric acid in the tank 102 has dropped to the lower-limit liquid level, the control device 4 determines that the tank 102 needs to be replenished with the sulfuric acid (Step S325). The control device 4 closes the opening/closing valve of the drain line 216 and opens the opening/closing valves 206 and 212 of the sulfuric-acid replenishment line 204 to start the replenishment of the tank 102 with the sulfuric acid (Step S326). When the liquid level sensor 103 detects that the liquid level of the sulfuric acid in the tank 102 has reached a predetermined upper-limit liquid level, the opening/closing valves 206 and 212 of the sulfuric-acid replenishment line 204 are closed to stop the replenishment of the tank 102 with the sulfuric acid (Step S327).

When the determination result in Step S324 is “No,” it is determined whether or not the total execution time of the preliminary drain operation is less than a predetermined period of time (Step S328). When the determination result in Step S328 is “Yes,” the preliminary drain operation continues to be executed until the amount of particles becomes smaller than the predetermined threshold (a loop composed of Steps S323, S324, and S328).

When the determination result of Step S328 is “No,” the control device 4 determines that there is some factor (for example, an abnormality in the sulfuric acid source 202 as a factory power) that makes it impossible to reduce the amount of particles below the predetermined threshold by the preliminary drain operation. Then, the control device 4 issues an alarm using a user interface of the substrate processing system 1 to prompt an operator to check such a status.

In the case in which the configuration of FIG. 6 is employed, when the amount of particles detected by the LPC 240 exceeds the predetermined threshold while the tank 102 is being replenished with the sulfuric acid, the opening/closing valve 212 may be immediately closed and the opening/closing valve 218 may be opened. This makes it possible to prevent contaminated sulfuric acid from being supplied to the tank 102 even if the amount of particles suddenly increases.

In a case in which the LPC 240 is configured to be able to detect the amount of particles for each particle size, a determination criterion (threshold) for the amount of particles may be set for each particle size.

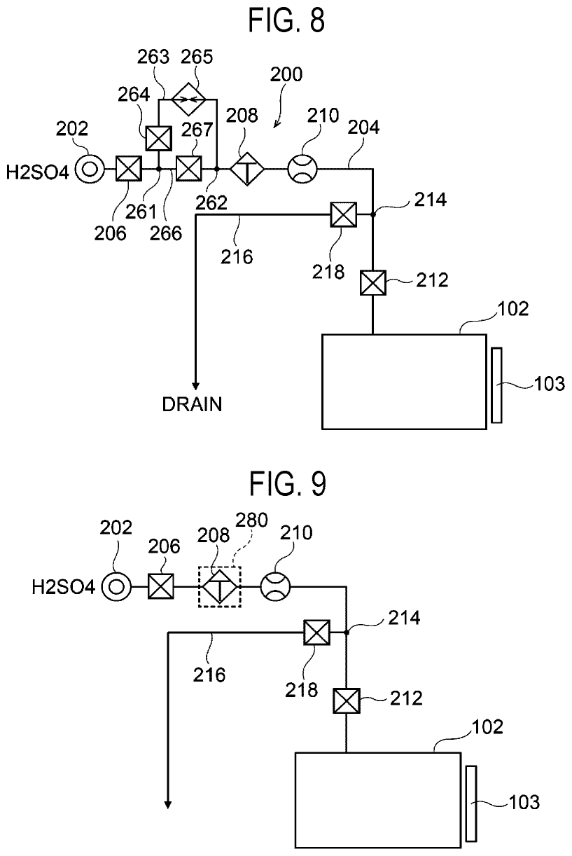

Next, still another embodiment (hereinafter also referred to as a fourth embodiment) of the sulfuric-acid replenishment mechanism will be described with reference to FIG. 8. The fourth embodiment is different from the first embodiment in that the preliminary drain operation is executed using heated sulfuric acid, and other features are the same as those in the first embodiment.

In the fourth embodiment, a heating bypass line 263 is connected to connection points 261 and 262 set between the opening/closing valve 206 and the filter 208 of the sulfuric-acid replenishment line 204. The heating bypass line 263 includes an opening/closing valve 264 and a heater 265 which are arranged sequentially from an upstream side. An opening/closing valve 267 is provided in a portion between the opening/closing valve 206 and the filter 208 of the sulfuric-acid replenishment line 204 (hereinafter also referred to as a “main line portion 266” for the sake of convenience in description). By switching between the opening/closing valves 264 and 267, the sulfuric acid supplied from the sulfuric acid source 202 may be made to flow only to one of the main line portion 266 and the heating bypass line 263.

In the fourth embodiment, whether or not to execute the preliminary drain operation is determined in the same manner as in the first embodiment. In the fourth embodiment, when the preliminary drain operation is executed, the opening/closing valves 206, 264, and 218 are opened with the opening/closing valves 267 and 212 closed, and the heater 265 is turned on (powered). At this time, the sulfuric acid flowing from the sulfuric acid source 202 into the sulfuric-acid replenishment line 204 flows into the heating bypass line 263 and passes through the heating bypass line 263. Thereafter, the sulfuric acid flows into the sulfuric-acid replenishment line 204 again and flows downward in the sulfuric-acid replenishment line 204. Subsequently, the sulfuric acid is discharged via the drain line 216.

When passing through the heating bypass line 263, the sulfuric acid is heated by the heater 265. Thus, the heated sulfuric acid passes through the filter 208. As a result, particles adhering to the filter element surface by the above-mentioned non-sieving mechanism are released from the filter element and flow out of the filter 208. In other words, the filter 208 may be actively cleaned by the preliminary drain operation. This may extend the lifetime of the filter.

The preliminary drain operation involving the cleaning of the filter 208 with the heated sulfuric acid does not have to be performed every time the preliminary drain operation is executed. For example, the preliminary drain operation involving the cleaning may be performed once every 10 preliminary drain operations. Alternatively, the preliminary drain operation involving the cleaning may be performed when performing maintenance on the processing liquid supply mechanism. When performing a normal preliminary drain operation (without the heated sulfuric acid), the opening/closing valves 206, 267, and 218 may be opened with the opening/closing valves 264 and 212 closed.

A flow resistance of the heating bypass line 263 may be set to be larger than that of the main line portion 266. This is because as a flow velocity of the sulfuric acid passing through the heater 265 is set as small as possible, a heating efficiency is increased. For this purpose, a pipe diameter of the heating bypass line 263 may be reduced, or an appropriate throttle may be provided in the heating bypass line 263. The opening/closing valve 264 may be replaced with a needle valve having a full closing function.

Next, still another embodiment (hereinafter also referred to as a fifth embodiment) of the sulfuric-acid replenishment mechanism will be described with reference to FIG. 9. The fifth embodiment is different from the first embodiment in that the preliminary drain operation is executed using the heated sulfuric acid, and other features are the same as those in the first embodiment.

In the fifth embodiment, the filter 208 is provided with a heater (heating device) configured to heat the filter 208, or a vibration device configured to apply vibration to the filter 208. The heating device or the vibration device is shown diagrammatically as a square box indicated by a broken line with reference numeral 280. By heating the filter 208 or applying the vibration to the filter 208, particles adhering to the filter element surface by the above-mentioned non-sieving mechanism are easily released from the filter element. The heating of the filter 208 or the application of the vibration to the filter 208 may be performed simultaneously with the preliminary drain operation, or may be performed slightly before the preliminary drain operation. In the latter case, the preliminary drain operation may be executed more efficiently, which shortens a time period required for the preliminary drain operation. Even in the fifth embodiment, the lifetime of the filter may be further prolonged due to the effect of cleaning the filter.

According to the above-described embodiments, it is possible to prevent the processing liquid containing contaminants such as particles from flowing into the tank 102. This makes it possible to suppress a deterioration of the cleanliness of the processing liquid supplied to the substrate W in each processing unit 16, and prevents a deterioration of a degree at which the substrate W is contaminated by the particles.

According to the present disclosure in some embodiments, it is possible to prevent a tank from being replenished with a processing liquid containing contaminants such as particles.

The embodiments disclosed herein should be considered to be illustrative and not restrictive in all respects. The above-described embodiments may be omitted, substituted, or modified in various forms without departing from the scope and spirit of the appended claims.

The substrate to be processed is not limited to a semiconductor wafer, but may be a variety of substrates used in the field of the semiconductor device manufacturing, such as a glass substrate, a ceramic substrate and the like. The processing liquid is also not limited to the sulfuric acid, but may be any processing liquid used in the field of the semiconductor device manufacturing, such as hydrogen peroxide, IPA, or the like.

What is claimed is:

1. A substrate processing apparatus comprising:
a processing unit configured to perform liquid processing on a substrate using a processing liquid;
a tank storing the processing liquid before being supplied to the processing unit;
a replenishment line through which the processing liquid is supplied from a processing liquid source to the tank;
a replenishment opening/closing valve configured to open/close the replenishment line;
a first drain line branched at the replenishment line on an upstream side of the replenishment opening/closing valve;
a first drainage opening/closing valve configured to open/close the first drain line; and
a controller configured to control the replenishment opening/closing valve and the first drainage opening/closing valve to execute a preliminary drain operation in which the processing liquid flowing from the processing liquid source into the replenishment line is drained via the first drain line before a replenishment of the processing liquid from the processing liquid source into the tank via the replenishment line begins.

2. The substrate processing apparatus of claim 1, wherein a filter is provided in the replenishment line, and
wherein the first drain line is branched at the replenishment line on a secondary side of the filter.

3. The substrate processing apparatus of claim 1, wherein the controller executes the preliminary drain operation when the replenishment of the processing liquid into the tank via the replenishment line is not continuously performed after a predetermined period of time.

4. The substrate processing apparatus of claim 3, wherein the controller executes the preliminary drain operation for the predetermined period of time or until the processing liquid is discharged from the first drain line by a predetermined amount.

5. The substrate processing apparatus of claim 2, further comprising: a particle detector configured to detect an amount of particles contained in the processing liquid in the replenishment line,
wherein the controller executes the preliminary drain operation when the amount of particles detected by the particle detector exceeds a predetermined threshold.

6. The substrate processing apparatus of claim 5, wherein the controller executes the preliminary drain operation until the amount of particles detected by the particle detector becomes lower than the predetermined threshold.

7. The substrate processing apparatus of claim 2, further comprising: a second drain line branched at the replenishment line on a primary side of the filter; and
a second drainage opening/closing valve configured to open/close the second drain line,
wherein the controller controls operations of the replenishment opening/closing valve and the first drainage opening/closing valve, and an operation of the second drainage opening/closing valve to execute a first preliminary drain operation in which the processing liquid flowing from the processing liquid source into the replenishment line is drained via the second drain line, before the replenishment of the processing liquid from the processing liquid source into the tank via the replenishment line begins, and subsequently, a second preliminary drain operation in which the drain of the processing liquid via the second drain line is stopped and the processing liquid is drained via the first drain line.

8. The substrate processing apparatus of claim 7, wherein the controller executes the first preliminary drain operation and the second preliminary drain operation when the replenishment of the processing liquid into the tank via the replenishment line is not continuously performed after a predetermined period of time.

9. The substrate processing apparatus of claim 8, wherein the controller executes the first preliminary drain operation for the predetermined period of time or until the processing liquid is discharged from the second drain line by a predetermined amount, and subsequently, executes the second preliminary drain operation for the predetermined period of time or until the processing liquid is discharged from the second drain line by the predetermined amount.

10. The substrate processing apparatus of claim 7, further comprising: a particle detector configured to detect an amount of particles contained in the processing liquid in the replenishment line,
wherein the controller executes the first preliminary drain operation and the second preliminary drain operation when the amount of particles detected by the particle detector exceeds a predetermined threshold.

11. The substrate processing apparatus of claim 10, wherein the controller executes the first preliminary drain operation for a predetermined period of time or until the processing liquid is discharged from the second drain line by a predetermined amount, and subsequently, executes the second preliminary drain operation until the amount of particles detected by the particle detector becomes lower than the predetermined threshold.

12. The substrate processing apparatus of claim 2, further comprising: a heater provided in the replenishment line on an upstream side of the filter,
wherein the controller heat controls the heater to heat the processing liquid passing through the filter when the preliminary drain operation is executed.

13. The substrate processing apparatus of claim 2, further comprising: a heater configured to heat the filter,
wherein the controller controls the heater to heat the filter when the preliminary drain operation is executed.

14. The substrate processing apparatus of claim 2, further comprising: a vibration device configured to vibrate the filter,
wherein the controller controls the vibration device to vibrate the filter when the preliminary drain operation is executed.

15. A method of replenishing a processing liquid into a tank of a substrate processing apparatus,
wherein the substrate processing apparatus comprises:
a processing unit configured to perform liquid processing on a substrate using a processing liquid;
a tank storing the processing liquid before being supplied to the processing unit;
a replenishment line through which the processing liquid is supplied from a processing liquid source to the tank;
a replenishment opening/closing valve configured to open/close the replenishment line;
a first drain line branched at the replenishment line on an upstream side of the replenishment opening/closing valve; and
a first drainage opening/closing valve configured to open/close the first drain line, and
wherein the method comprises:
executing a preliminary drain operation in which the processing liquid flowing from the processing liquid source into the replenishment line is drained via the first drain line before a replenishment of the processing liquid from the processing liquid source into the tank via the replenishment line begins.

16. The method of claim 15, wherein a filter is provided in the replenishment line, and
wherein the first drain line is branched at the replenishment line on a secondary side of the filter.

17. The method of claim 15, wherein the preliminary drain operation is executed when the replenishment of the processing liquid into the tank via the replenishment line is not continuously performed after a predetermined period of time.
